(19) United States
(12) Patent Application Publication
(10) Pub. No.: US 2008/0135949 A1
(43) Pub. Date: Jun. 12, 2008

(54) Stacked silicon-germanium nanowire structure and method of forming the same

(75) Inventors: Guo Qiang Lo, Singapore (SG); Lakshmi Kanta Bera, Singapore (SG); Hoai Son Nguyen, Singapore (SG); Navab Singh, Singapore (SG)

Correspondence Address: SEED INTELLECTUAL PROPERTY LAW GROUP PLLC, 701 FIFTH AVE, SUITE 5400, SEATTLE, WA, 98104, US

(73) Assignee: Agency for Science, Technology and Research, Centros (SG)

(21) Appl. No.: 11/636,381

(22) Filed: Dec. 8, 2006

(51) Int. Cl. H01L 29/94

(52) U.S. Cl. 257/401; 438/197; 438/480; 257/E29.345

(57) ABSTRACT

A method of forming a stacked silicon-germanium nanowire structure on a support substrate is disclosed. The method includes forming a stacked structure on the support substrate, the stacked structure comprising at least one channel layer and at least one interchannel layer deposited on the channel layer; forming a fin structure from the stacked structure, the fin structure comprising at least two supporting portions and a fin portion arranged there between; oxidizing the fin portion of the fin structure thereby forming the silicon-germanium nanowire being surrounded by a layer of oxide; and removing the layer of oxide to form the silicon-germanium nanowire. A method of forming a gate-all-around transistor comprising forming a stacked silicon-germanium nanowire structure that has been formed on a support substrate is also disclosed. A stacked silicon-germanium nanowire structure and a gate-all-around transistor comprising the stacked silicon-germanium nanowire structure are also disclosed.

### FIELD OF THE INVENTION

The present invention relates to the field of nanowires, and in particular, to stacked silicon-germanium (SiGe) nanowire structure and a method of forming the same. The present invention also relates to a gate-all-around (GAA) transistor comprising the stacked silicon-germanium nanowire structure and a method of forming the same.

### BACKGROUND OF THE INVENTION

Driven by their unique properties, semiconductor nanowires (NW) are emerging to be a major research focus in nanotechnology area. Nanowire-based MOSFETs are projected as the candidates for end-of-the-roadmap devices for CMOS technology because they provide excellent electrostatic gate control of the channel. Various methods of achieving pseudo-ID semiconductor nanowires such as vapor-liquid-solid mechanism, Metal Organic Chemical Vapor Deposition (MOCVD) or Chemical Vapor Deposition (CVD), Molecular-beam epitaxy (MBE), for example have been reported in publications. These methods include the gold (Au)-nano cluster initiated nucleation for axially elongated Ge epitaxial core nanowires with i-Ge shell [A. B. Greytak et al., Appl. Phys. Lett., 84(21), (2004), p. 4176] by Stanford University group, and Si shell [J. Xiang et al., Nature, 441, (2006), p. 489], as recently reported by Harvard University group.

Typically, these NWs are randomly spread over the substrate and it requires complicated techniques to integrate them in a device architecture for achieving specific functionalities. Some of the techniques reported for this purpose are ‘pick-and-place’ with atomic force microscope (AFM) tip [G. Li et al., IEEE Intl Conf. on Robotics & Automation, 428 (2004)], liquid suspension, electric- or magnetic-field schemes [M. Law et al., Annu. Rev. Mater. Res., 34, 83 (2004)], or fluid flow [H. Yu et al., Science, 291, 30 (2001)]. However, such processes still lack control in precision, repeatability, and scalability. In addition, these methods are far from being capable of building nanowire network in a 3D-stack configuration in an orderly manner.

Several attempts have been made to address these problems so as to enable integration of nanowires in a device architecture. Amongst them are multi-bridge silicon channel devices which have been fabricated with SiGe sacrificial layers. United States Patent Application 2006/0024874 discloses a multi-bridge-channel MOSFET (MBCFET) which may be developed by forming a stacked structure on a substrate that includes channel layers and interchannel layers interposed between the channel layers. Trenches are formed by selectively etching the stacked structure. The trenches run across the stacked structure parallel to each other and separate a first stacked portion including channel patterns and interchannel patterns from second stacked portions including channel and interchannel layers remaining on both sides of the first stacked portion. First source and drain regions are grown using selective epitaxial growth. The first source and drain regions fill the trenches and connect to second source and drain regions defined by the second stacked portions. Marginal sections of the interchannel patterns of the first stacked portion are selectively exposed. Through tunnels are formed by selectively removing the interchannel patterns of the first stacked portion beginning with the exposed marginal sections. The through tunnels are surrounded by the first source and drain regions and the channel patterns. A gate is formed along with a gate dielectric layer, the gate filling the through tunnels and extending onto the first stacked portion.

United States Patent Application 2006/0091481 discloses a field effect transistor (FET) which includes spaced apart source and drain regions disposed on a substrate and at least one pair of elongate channel regions disposed on the substrate and extending in parallel between the source and drain regions. A gate insulating region surrounds the at least one pair of elongate channel regions, and a gate electrode surrounds the gate insulating region and the at least one pair of elongate channel regions. Support patterns may be interposed between the semiconductor substrate and the source and drain regions. The elongate channel regions may have sufficiently small cross-section to enable complete depletion thereof. For example, a width and a thickness of the elongate channel regions may be in a range from about 10 nanometers to about 20 nanometers. The elongate channel regions may have rounded cross-sections, e.g., each of the elongate channel regions may have an elliptical cross-section. The at least one pair of elongate channel regions may include a plurality of stacked pairs of elongate channel regions.

United States Patent Application 2006/0216897 discloses a field-effect transistor (FET) with a round-shaped nanowire channel and a method of manufacturing the FET are provided. According to the method, source and drain regions are formed on a semiconductor substrate. A plurality of preliminary channel regions is coupled between the source and drain regions. The preliminary channel regions are etched, and the etched preliminary channel regions are annealed to form FET channel regions, the FET channel regions having a substantially circular cross-sectional shape.

### SUMMARY OF THE INVENTION

In one embodiment of the invention, a method of forming a stacked silicon-germanium nanowire structure on a support substrate is provided. The method includes forming a stacked structure on the support substrate, the stacked structure comprising at least one channel layer and at least one interchannel layer deposited on the channel layer; forming a fin structure from the stacked structure, the fin structure comprising at least two supporting portions and a fin portion arranged there between; oxidizing the fin portion of the fin structure thereby forming the silicon-germanium nanowire being surrounded by a layer of oxide; and removing the layer of oxide to form the silicon-germanium nanowire.

In another embodiment of the invention, a method of forming a gate-all-around transistor comprising forming a stacked silicon-germanium nanowire structure that has been formed on a support substrate is provided. The method of forming the gate-all-around transistor further includes forming a second insulating layer around the silicon-germanium nanowire; depositing a semiconductor layer on the second insulating layer; forming a gate electrode from the semiconductor layer; doping at least the supporting portions with a first dopant.

In another embodiment of the invention, a stacked silicon-germanium nanowire structure is provided. The stacked silicon-germanium nanowire structure includes a support substrate; a stacked fin structure arranged on the support substrate, wherein the stacked fin structure comprises at least one channel layer and at least one interchannel layer deposited on the channel layer and further comprises at least two supporting portions and at least one silicon-germanium nanowire arranged there between.

In a further embodiment of the invention, a gate-all-around transistor comprising the stacked silicon-germanium nanowire structure is provided. The gate-all-around transistor further includes a second insulating layer around the silicon-germanium nanowire; a gate electrode positioned over the second insulating layer; and at least two doped supporting portions.

The following figures illustrate various exemplary embodiments of the present invention. However, it should be noted that the present invention is not limited to the exemplary embodiments illustrated in the following figures.

### BRIEF DESCRIPTION OF THE DRAWINGS

FIGS. 1A to 1D show a process flow of a method of forming a stacked silicon-germanium nanowire structure on a support substrate according to an embodiment of the present invention;

FIG. 2 shows a flow chart of a method of forming a gate-all-around transistor comprising forming a stacked silicon-germanium nanowire structure that has been formed on a support substrate according to an embodiment of the present invention;

FIG. 3 shows a cross-sectional view of a plurality of multilayer stacked fin structures arranged on a buried oxide (BOX) layer according to an embodiment of the present invention;

FIG. 4 shows a cross-sectional view of a stacked silicon-germanium nanowire structure after oxidation according to an embodiment of the present invention;

FIG. 5 shows a scanning electron microscopy (SEM) image of a silicon-germanium multilayer stacked structure according to an embodiment of the present invention;

FIG. 6A shows a SEM image of a multilayer stacked fin structure after fin etch and clean according to an embodiment of the present invention; FIG. 6B shows a SEM image of a plurality of multilayer stacked fin structures after fin etch and clean according to an embodiment of the present invention

FIG. 7A shows a SEM image of a multilayer stacked silicon-germanium nanowire structure after oxide release according to an embodiment of the present invention; FIG. 7B shows a SEM image of a plurality of multilayer stacked silicon-germanium nanowire structure after oxide release according to an embodiment of the present invention;

FIG. 8A shows a Transmission Electron Microscopy (TEM) image of a 2-storied vertically stacked silicon-germanium nanowire Gate-All-Around Metal Oxide Semiconductor Field-Effect Transistor (MOSFET) according to an embodiment of the present invention; FIG. 8B shows a Transmission Electron Microscopy (TEM) image of a 3-storied vertically stacked silicon-germanium nanowire Gate-All-Around (GAA) Metal Oxide Semiconductor Field-Effect Transistor (MOSFET) according to an embodiment of the present invention; FIG. 8C shows a Transmission Electron Microscopy (TEM) image of a 4-storied vertically stacked silicon-germanium nanowire Gate-All-Around Metal Oxide Semiconductor Field-Effect Transistor (MOSFET) according to an embodiment of the present invention;

FIG. 9 shows a TEM image and Energy Dispersive X-ray (EDX) analysis of germanium concentration in the nanowire according to an embodiment of the present invention;

FIG. 10 shows a TEM image showing gate oxide thickness and nanowire width according to an embodiment of the present invention;

FIG. 11 shows a I_{D}-V_{G} characteristics plot of a GAA silicon-germanium nanowire p-channel MOSFET with a vertically stacked 3 nanowire bundle according to an embodiment of the present invention;

FIG. 12 shows a I_{D}-V_{D} characteristics plot of a GAA silicon-germanium nanowire p-channel MOSFET with a vertically stacked 3 nanowire bundle according to an embodiment of the present invention;

FIG. 13 shows a I_{D}-V_{G} characteristics plot of a GAA silicon-germanium nanowire p-channel MOSFET with two vertically stacked 3 nanowire bundle (6 nanowire bundle) according to an embodiment of the present invention;

FIG. 14 shows a I_{D}-V_{D} characteristics plot of a GAA silicon-germanium nanowire p-channel MOSFET with two vertically stacked 3 nanowire bundle (6 nanowire bundle) according to an embodiment of the present invention;

FIG. 15 shows a I_{D}-V_{G} characteristics plot of a GAA silicon-germanium nanowire p-channel MOSFET with five vertically stacked 3 nanowire bundle (15 nanowire bundle) according to an embodiment of the present invention;

FIG. 16 shows a I_{D}-V_{D} characteristics plot of a GAA silicon-germanium nanowire p-channel MOSFET with five vertically stacked 3 nanowire bundle (15 nanowire bundle) according to an embodiment of the present invention;

FIG. 17 shows a plot of subthreshold slope (SS) with gate length (L_{G}) of a GAA silicon-germanium nanowire p-channel MOSFET with five vertically stacked 3 nanowire bundle (15 nanowire bundle) according to an embodiment of the present invention;

FIG. 18 shows a plot of threshold voltage (V_{TH}) with gate length (L_{G}) of a GAA silicon-germanium nanowire p-channel MOSFET with five vertically stacked 3 nanowire bundle (15 nanowire bundle) according to an embodiment of the present invention;

FIG. 19 shows a plot of saturation drain current (I_{DSAT}) with number of nanowires according to an embodiment of the present invention;

FIG. 20 shows a plot of transconductance (G_{M}) with gate voltage (V_{G}) of a p-channel MOSFET for a varying number of nanowires according to an embodiment of the present invention;

FIG. 21 shows a I_{D}-V_{G} characteristics plot of a GAA silicon-germanium nanowire n-channel MOSFET with a vertically stacked 2 nanowire bundle according to an embodiment of the present invention;

### DETAILED DESCRIPTION OF THE INVENTION

Exemplary embodiments of a stacked silicon-germanium nanowire structure, a gate-all-around transistor comprising the stacked silicon-germanium nanowire structure and their methods of forming the same are described in details below with reference to the accompanying figures. In addition, the exemplary embodiments described below can be modified in various aspects without changing the essence of the invention.

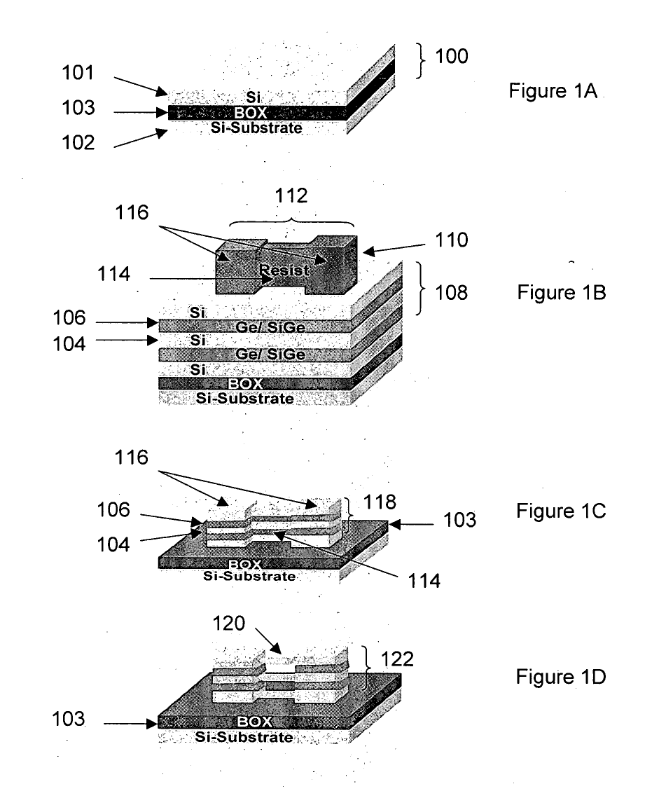

FIG. 1A to 1D shows a process flow of a method of forming a stacked silicon-germanium nanowire structure on a support substrate according to an embodiment of the present invention. The method starts with a silicon-on-insulator (SOI) wafer 100 as a starting substrate in FIG. 1A. However, the starting substrate is not limited to SOI, it can be bulk Silicon, or other relevant substrates depending on the applications. SOI is used as an example for the clarity of description in the present application. The SOI wafer 100 includes a semiconductor device layer 101 separated vertically from a support substrate 102 by an insulating layer or a buried oxide (BOX) layer 103. The BOX layer 103 electrically isolates the device layer 101 from the support substrate 102. The SOI wafer 100 may be fabricated by any standard techniques, such as wafer bonding or a separation by implantation of oxygen (SIMOX) technique. The SOI wafer 100 can also be considered as a support substrate.

In the illustrated embodiment of the invention in FIG. 1A, the device layer 101 is typically Si but may be formed from any suitable semiconductor materials including, but not limited to poly-silicon, gallium arsenide (GaAs), germanium (Ge) or silicon-germanium (SiGe). The device layer 101 may be about 700 Angstrom thick but is not so limited. The support substrate 102 may be formed from any suitable semiconductor materials including, but not limited to Si, sapphire, polysilicon, silicon oxide (SiO₂) or silicon nitride (Si₃N₄). The BOX layer 103 is usually an insulating layer. The BOX layer 103 is typically SiO₂ but may be formed from any suitable insulating materials including, but not limited to tetraethylorthosilicate (TEOS), Silane (SiH₄), silicon nitride (Si₃N₄) or silicon carbide (SiC). The BOX layer 103 may be about 1500 Angstrom thick but is not so limited.

A surface clean step may be carried out with RCA and hydrogen fluoride (HF) prior to any subsequent deposition. Contaminants present on the surface of silicon wafers at the start of processing, or accumulated during processing, have to be removed at specific processing steps in order to obtain high performance and high reliability semiconductor devices, and to prevent contamination of process equipment, especially the high temperature oxidation, diffusion, and deposition tubes or chambers. The RCA clean is the industry standard for removing contaminants from wafers. The RCA cleaning procedure usually has three major steps used sequentially: Organic Clean (removal of insoluble organic contaminants with a 5:1:1 H₂O:H₂O₂:NH₄OH solution), Oxide Strip (removal of a thin silicon dioxide layer using a diluted 50:1 dionized-water H₂O:HF solution) and Ionic Clean (removal of ionic and heavy metal atomic contaminants using a solution of 6:1:1 H₂O:H₂O₂:HCl).

After the surface clean step, channel layer 104 and interchannel layer 106 may be alternatively deposited on the SOI wafer 100 using a cold wall Ultra High Vacuum Chemical Vapor Deposition (UHVCVD) reactor at a temperature of about 600° and utilizing silane (SiH₄) for Si and a combination of SiH₄ and germane (GeH₄) for SiGe to form the multilayer stacked structure 108 in FIG. 1B. In the illustrated embodiment of the invention in FIG. 1B, the channel layer 104 is typically Si and the interchannel layer 106 is typically Ge but not so limited (for instance, can be SiGe, whereas Ge-concentration as designed for concern of final applications requirements). The thickness of each Si channel layer 104 is about 50 nm but is not so limited while that of each Ge interchannel layer 106 is about 60 nm but is not so limited. Growth of the Ge interchannel layer 106 may be a two-step epitaxy process if the respective Si channel 104 and Ge interchannel 106 layers are relatively thick. The two-step process includes deposition of an additional thin SiGe buffer layer on the Si channel layer 104 before growth of 100% Ge interchannel layer 106. The purpose of buffer layer is to provide a grading or transition from one semiconductor structure to the other when their lattices mismatch is large (for example, Si vs. Ge is about 4% mismatch). The buffer layer's lattice constant usually falls between the original adjacent films, so the mismatches to those adjacent films can be less, thus the overall mechanical stress in the system of the total stacked films is minimized. Thereby, the buffer layer reduces the stress caused by the lattice mismatch between the respective Si channel layer 104 and Ge interchannel layer 106. However, if the respective Si channel layer 104 and Ge interchannel layer 106 are relatively thin, then the deposition of the additional SiGe buffer layer may be optional, since the thin layer has less stress force on the others.

After the Si channel 104 and Ge interchannel 106 multilayer deposition, a photoresist layer 110 is applied or coated onto the top surface of the multilayer stacked structure 108. The photoresist layer 110 is then patterned to form a fin structure 112 including a fin portion 114 arranged in between two supporting portions 116 by standard photolithography techniques, for example 248 nm krypton fluoride (KrF) lithography. Alternating-Phase-Shift mask (AltPSM) may be used to pattern the narrow fin portion 114 which may be about 60 nm but is not so limited. Subsequently, using the patterned photoresist layer 110 as a mask, portions of the multilayer stacked structure 108 not covered by the mask may be etched away by a suitable etching process such as a dry etching process for example reactive-ion-etching (RIE) in Sulfur Hexafluoride (SF₆).

In FIG. 1C, a resultant multilayer stacked fin structure 118 comprising of a fin portion 114 arranged in between and connected at each end to a respective supporting portion 116 is formed on the BOX layer 103. The fin portion 114 acts as a bridge linking the respective supporting portions 116. The supporting portions 116 are typically blocks with a wider dimension when compared to the fin portion 114. FIG. 1 shows that the fin portion 114 is arranged in the middle between the two supporting portions 116. Alternatively, the fin portion 114 can also be arranged towards either side of the two supporting portions 116.

After forming the multilayer stacked fin structure 118, the photoresist layer 110 is removed or stripped away by a photoresist stripper (PRS). Photoresist stripping, or simply ‘resist stripping’, is the removal of unwanted photoresist layer from the wafer. Its objective is to eliminate the photoresist material from the wafer as quickly as possible, without allowing any surface material under the photoresist to be attacked by the chemicals used. In this regard, any other suitable techniques or processes may also be used in order to provide greater flexibility with respect to forming of the fin structure comprising the fin portion arranged in between two supporting portions on the BOX layer.

The fin portion 114 of the multilayer stacked fin structure 118 is then subjected to an oxidation process (as part of the Ge condensation process). As described by publication “SiGe-on-Insulator and Ge-on-Insulator Substrates Fabricated by Ge-Condensation Technique for High-Mobility Channel CMOS Devices”, Tsutomu Tezuka et al., Materials Research Society, the Ge-condensation process consists of an epitaxial growth of a SiGe layer with a low Ge fraction on a SOI wafer and successive oxidation at high temperatures, which can be incorporated in conventional CMOS processes. During the oxidation (or condensation), Ge atoms are pushed out from the oxide layer and condensed in the remaining SiGe layer. The interface between the Si and SiGe layers disappeared due to the interdiffusion of Si and Ge atoms. Eventually, a SiGe-on-Insulator (SGOI) layer with a higher Ge fraction is formed. The Ge fraction in the SGOI layer can be controlled by the oxidation time (or the thickness of SiGe, Ge, Ge concentration in SiGe film, and also the initial Si layer thickness) because total amount of Ge atoms in the SGOI layer is conserved throughout the oxidation process.

In FIG. 1C, the Si 104, Ge 106 and SiGe layers in the fin portion 114 are oxidized at about 750° for about 60 minutes in dry oxygen ambient. From publication “Advantages of Ge (111) surface for high quality HfO₂/Ge interface”, Masahiro Toyama et al., Extended Abstracts of the 2004 International Conference on Solid State Devices and Materials, Tokyo, 2004, pp. 226-227, it is known that the oxidation rate of Ge 106 and SiGe is faster than that for Si 104 and thus after the oxidation step, the Ge 106 and SiGe layers get fully oxidized leaving core wires of Si 104. In addition, during the oxidation, Ge 106 gets inter-mixed into the adjacent Si layer 104 surfaces and thus Si 104 becomes an alloy mixture of SiGe at the nanowire surface due to the Ge condensation process. Higher Ge-content SiGe nanowire can be obtained when the fin portion 114 is subjected to a longer oxidation period.

A cyclic annealing step may be carried out at temperatures of about 750° and about 900° but not so limited. Approximately five cycles of annealing with durations of about 10 minutes at each temperature were used to repair the crystal defects. The defects could arise from the imperfection of films deposition, initial mismatching of layer by layer stack-up, RIE plasma bombardment induced surface or sidewall damages, for example.

Subsequently, the oxidized Ge 106 and SiGe were etched using dilute hydrofluoric acid (DHF) (1:200) to release the SiGe nanowires 120. But any other suitable etchant can also be used to release the SiGe nanowires 120. The dimension of each SiGe nanowire 120 is about 20 nm to 30 nm but not so limited. The diameter of each SiGe nanowire 120 may be determined by the initial layer deposition and oxidation cycles. The result is a stacked SiGe nanowire structure 122 on the BOX layer 103 or support substrate 102 as shown in FIG. 1D.

Subsequently to form a gate-all around transistor comprising the stacked SiGe nanowire structure, the nanowire release may be followed by an oxide growth with resultant oxide thickness of about 4 nm but not so limited by a dry oxidation process at a temperature of between about 800° to about 900° or by a CVD process to form the gate dielectric. The gate dielectric may be any suitable dielectric such as nitride, high-k dielectrics (for example Hafnium Oxide (HfO₂), Hafnium lanthanide oxide (HfLaO), Aluminium oxide (Al₂O₃), but not so limited. Next, a conductive layer of about 1300 Angstrom thick is deposited over the oxide layer. The conductive layer may be silicon, polysilicon, amorphous silicon, metal such as Tantalum Nitride (TaN) but not so limited. This is followed by patterning and etching of the conductive layer to form the gate electrode. The minimum gate length is about 150 nm and the maximum gate length is about 1 μm. The gate electrode can be deposited as intrinsically undoped, different doping based on the doping methods or as metal gates.

Subsequently, the supporting regions of the multilayer stacked fin structure were implanted with a p-type dopant, for example BF₂ with a dose of about 4×10¹⁵ cm⁻² at about 35 keV to form the respective source and drain region for a p-channel MOSFET transistor. Any other suitable p-type dopant such as aluminum, gallium and indium may also be used. Incidentally, the nanowires are without any intentional doping and thus the combination of gate electrode types and dopants adopted for the source or drain implant define whether the transistor will be a p-channel MOSFET transistor or an n-channel MOSFET transistor. To realize n-channel MOSFET transistor in some wafers, about 4×10¹⁵ cm⁻² dose of n-type dopant such as Arsenic (As) at 30 keV may be implanted in the supporting regions. Any other suitable n-type dopants such as phosphorous (P), antimony (Sb), bismuth (Bi) may also be used.

After the respective dopant implant, a source and drain activation anneal step at a temperature of approximately 950° for 15 minutes may be carried out to ensure uniform diffusion of dopants in the gate electrode (if it has been doped) and in the thick nanowire extension regions beneath the gate, thereby reducing the effective channel length. The process of forming the gate-all around transistor comprising the stacked SiGe nanowire structure may be completed by the standard metal contact formation and sintering steps.

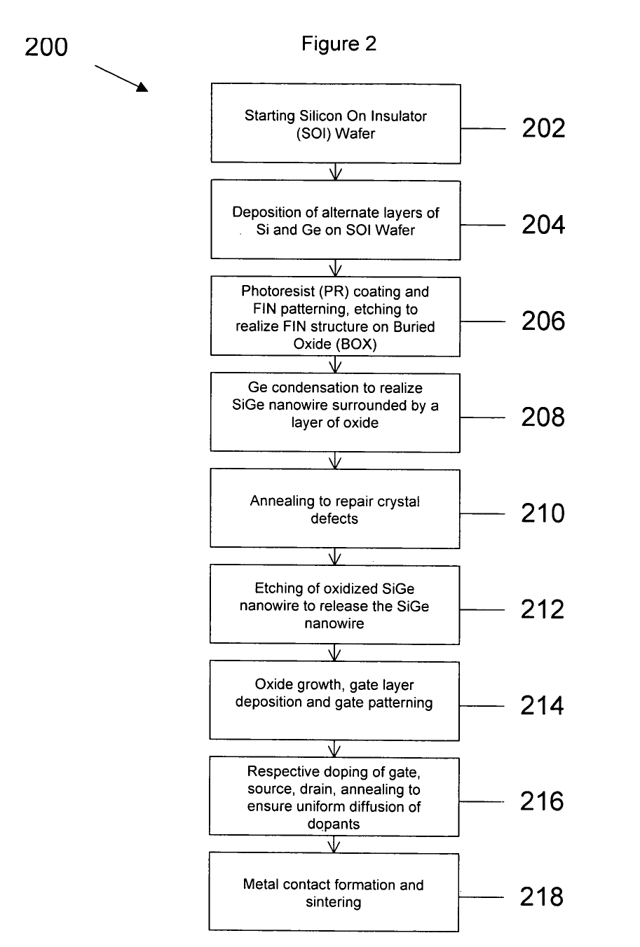

FIG. 2 shows a flow chart of a method of forming a gate-all-around transistor comprising forming a stacked silicon-germanium nanowire structure that has been formed on a support substrate according to an embodiment of the present invention. The method 200 begins at 202 with a starting SOI wafer 100 comprising a device layer 101 separated vertically from a support substrate 102 by a BOX layer 103. Next, in 204 alternate layers of Si 104 and Ge 106 are deposited on the SOI wafer 100 to form a multilayer stacked structure 108 on the SOI wafer 100. In 206, a photoresist layer 110 is coated onto a top surface of the multilayer stacked structure 108. The photoresist layer 110 is then patterned to form a fin structure 112 including a fin portion 114 arranged in between two supporting portions 116 by standard photolithography techniques. Using the fin pattern photoresist layer 110 as a mask, portions of the multilayer stacked structure 108 not covered by the mask are etched away to realize a multilayer stacked fin structure 118 comprising of a fin portion 114 arranged in between two supporting portions 116 on the BOX layer 103. In 208, the fin portion 114 of the multilayer stacked fin structure 118 is further subjected to a Ge condensation process to achieve a stacked SiGe nanowire structure 122 with the SiGe nanowire 120 being surrounded by a layer of oxide. Subsequently in 210, the stacked SiGe nanowire structure 122 is subject to an annealing step to repair the crystal defects. Next in 212, the oxidized SiGe nanowire is etched to release the SiGe nanowire 120 forming the resultant stacked SiGe nanowire structure 122. In 214, a layer of oxide is grown on the SiGe nanowire and this is followed by conductive layer deposition, gate patterning and etching to form the gate electrode. In 216, the supporting portions 116 are doped to form the source and drain regions of the respective MOSFET transistor. The gate electrode may also be doped with the same or different dopant as that of the resultant source and drain regions. This is followed by an annealing step to ensure uniform diffusion of dopants in the gate electrode and in the nanowire extension regions beneath the gate electrode. In 218, the method of forming a gate-all-around transistor comprising forming a stacked silicon-germanium nanowire structure 122 that has been formed on a support substrate 102 may be completed with the standard metal contact formation and sintering steps.

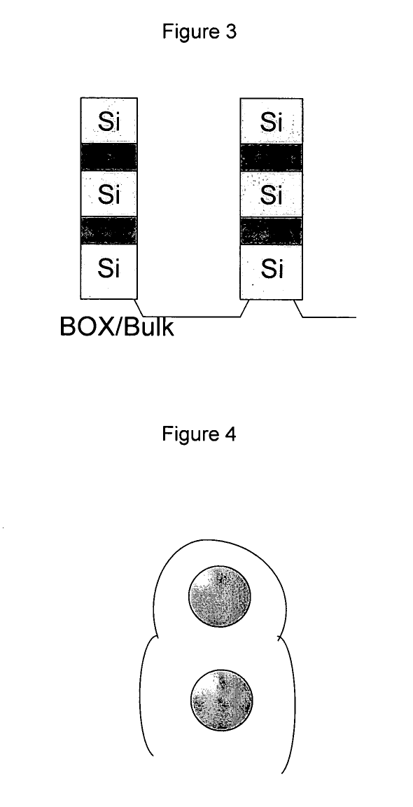

FIG. 3 shows a cross-sectional view of a plurality of multilayer stacked fin structures arranged on a BOX layer according to an embodiment of the present invention. A single multilayer stacked fin structure or a plurality of multilayer stacked fin structures, each comprising of a fin portion arranged in between two supporting portions may be formed on the BOX layer. The multilayer stacked fin structures may be arranged parallel to each other, horizontally on the support substrate or in any other desired manner.

FIG. 4 shows a cross-sectional view of a stacked silicon-germanium nanowire structure after oxidation according to an embodiment of the present invention. When the multilayer stack structure is subjected to an oxidation process, the original SiGe layer will oxidize faster than the Si layer because Ge increases the oxidation rate. Due to the Ge condensation process, Ge will be segregated into the slower oxidized Si core, thereby forming the SiGe nanowires.

### Results

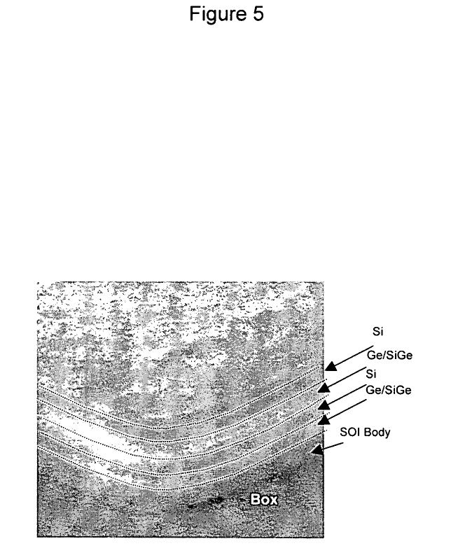

FIG. 5 shows a scanning electron microscopy (SEM) image of a silicon-germanium multilayer stacked structure according to an embodiment of the present invention. Alternate layers of Si and Ge/SiGe are deposited on the SOI wafer, creating a multilayer stacked structure.

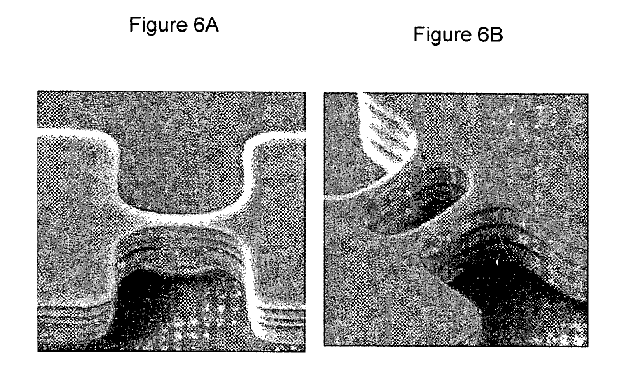

FIG. 6A shows a SEM image of a multilayer stacked fin structure after fin etch and clean according to an embodiment of the present invention and FIG. 6B shows a SEM image of a plurality of multilayer stacked fin structures after fin etch and clean according to an embodiment of the present invention. Clear interfaces can be observed for each layer.

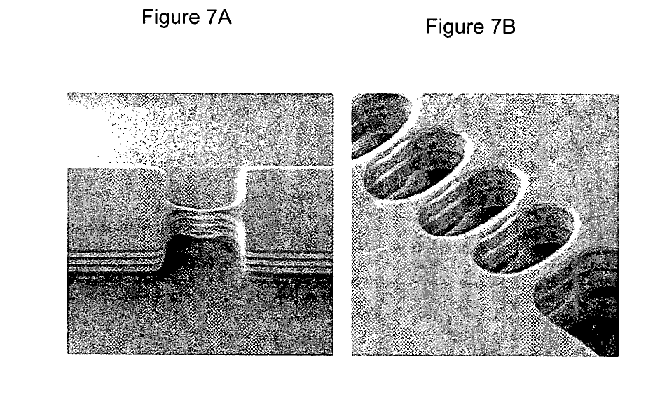

FIG. 7A shows a SEM image of a multilayer stacked silicon-germanium nanowire structure after oxide release according to an embodiment of the present invention and FIG. 7B shows a SEM image of a plurality of multilayer stacked silicon-germanium nanowire structure after oxide release according to an embodiment of the present invention. Three-dimensional stacks of SiGe nanowire array bridges are clearly observed after the oxide release.

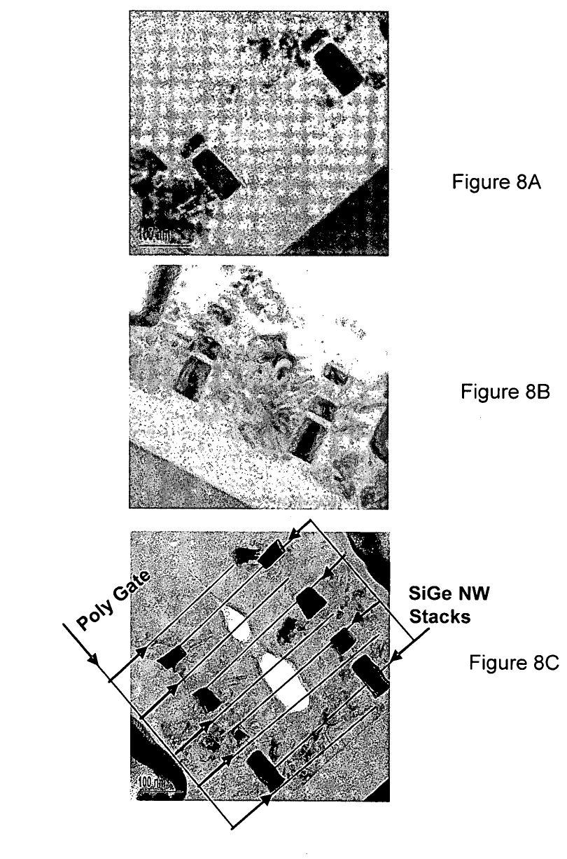

FIG. 8A shows a Transmission Electron Microscopy (TEM) image of a 2-storied vertically stacked silicon-germanium nanowire Gate-All-Around Metal Oxide Semiconductor Field-Effect Transistor (MOSFET) according to an embodiment of the present invention, FIG. 8B shows a Transmission Electron Microscopy (TEM) image of a 3-storied vertically stacked silicon-germanium nanowire Gate-All-Around (GAA) Metal Oxide Semiconductor Field-Effect Transistor (MOSFET) according to an embodiment of the present invention and FIG. 8C shows a Transmission Electron Microscopy (TEM) image of a 4-storied vertically stacked silicon-germanium nanowire Gate-All-Around Metal Oxide Semiconductor Field-Effect Transistor (MOSFET) according to an embodiment of the present invention. The TEM cross-sectional images of the SiGe GAA MOSFET transistors after the completed process are shown in FIG. 8A, FIG. 8B, and FIG. 8C. Vertical stacks of 2-, 3-, and 4-nanowires are realized for the MOSFET channels as seen in the respective TEM images, but not so limited. The nanowires could be stacked up to any desired number of stories depending on requirements. The high surface to volume ratio of nanowires renders the GAA MOSFET suitable for sensor applications. In FIG. 8A, FIG. 8B, and FIG. 8C, the gate electrode completely surrounds each nanowire.

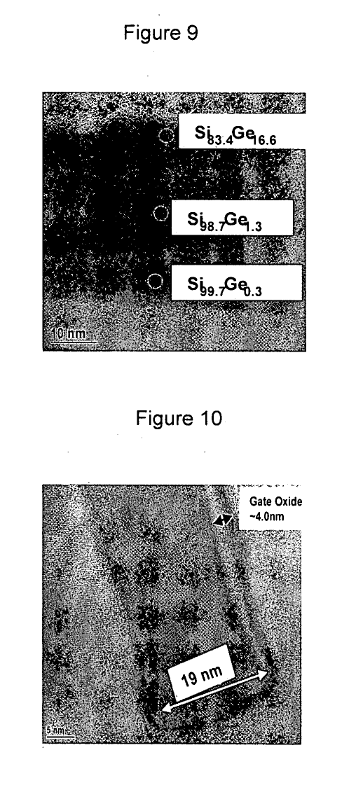

FIG. 9 shows a TEM image and Energy Dispersive X-ray (EDX) analysis of germanium concentration in the nanowire according to an embodiment of the present invention. The EDX analysis results in FIG. 9 indicates that the Ge concentration is much higher near the nanowire surface and it reduces significantly towards the core of the nanowire. The Ge concentration at the surface of the nanowire is about 16.6%, reduces to about 1.3% and then reduces to 0.3% towards the core of the nanowire. This is similar to the observation as reported in the publication by Takeuchi et al. [H. Takeuchi et al., App. Phy. Lett., 80, 20, pp. 3706-3708 (2002)] [16] who discloses that a rapid intermixing of Si and Ge at the interface in the initial phase of annealing of Ge films on Si with insignificant Ge diffusion after the initial phase.

FIG. 10 shows a TEM image showing gate oxide thickness and nanowire width according to an embodiment of the present invention. The minimum nanowire diameter is about 19 nm as seen from the TEM image in FIG. 10. It should be noted that the dimension can be further narrowed down by optimizing the oxidation and etching steps. The TEM micrograph in FIG. 10 also shows the gate dielectric thickness to be about 4 nm. The slight non-uniformity in oxide thickness seen in the micrograph may be due to the non-uniform Ge concentration at the surfaces.

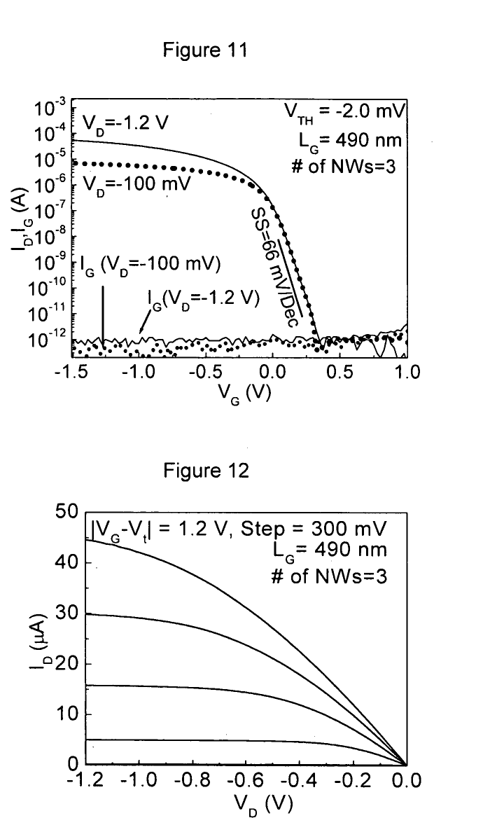

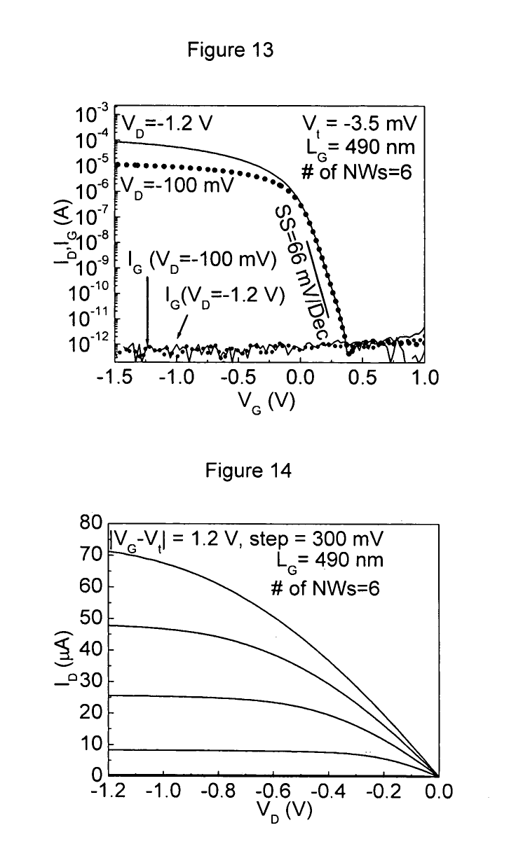

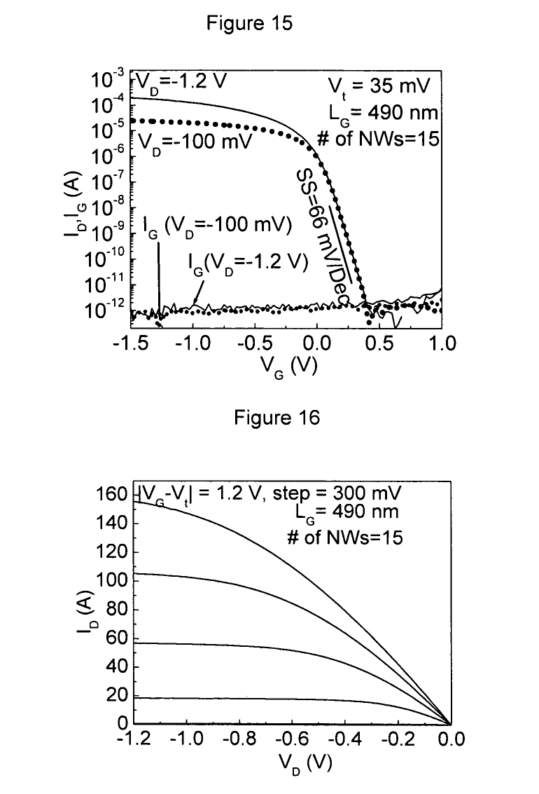

The stacked silicon-germanium nanowire MOSFET transistors were characterized using a HP4156A parametric analyzer. FIGS. 11 to 16 show the I_{D}-V_{G} and I_{D}-V_{D} characteristics plot of the respective GAA SiGe nanowire p-channel MOSFET transistors with 1, 2 and 5 rows of 3 nanowire bundle with gate length L_{G} of about 490 nm. The transistors show excellent performance in terms of their sub-threshold slopes and gate leakage characteristics. The Iₒₙ and I_{off} were measured at V_{G}(On)=Vₜₕ−0.7V_{dd}, and V_{G}(Off)=Vₜₕ+0.3V_{dd} respectively for the p-channel MOSFET transistors. V_{D} is about 1.2 V in all the measurements. The transistors show high Iₒₙ/I_{off} ratio of approximately 1×10⁷.

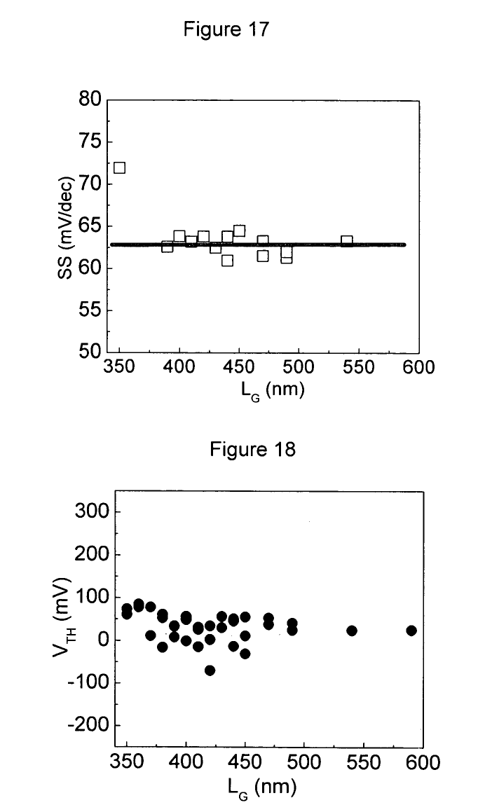

FIG. 17 shows a plot of subthreshold slope (SS) with gate length (L_{G}) of a GAA silicon-germanium nanowire p-channel MOSFET with five vertically stacked 3 nanowire bundle (or 3-storied) (15 nanowire bundle) according to an embodiment of the present invention. Sub-threshold slopes for different L_{G} have been plotted in FIG. 17 and nearly ideal sub-threshold slopes of approximately 62 mV/dec have been obtained in most of the cases. It is noted that despite the different L_{G} and V_{D}, gate current (I_{G}) remains invariant with the lowest value of about 6.0×10⁻¹³ A which is the leakage limit of the measurement setup used, thereby indicating good quality gate oxide formation in all surfaces of the nanowires.

FIG. 18 shows a plot of threshold voltage (V_{TH}) with gate length (L_{G}) of a GAA silicon-germanium nanowire p-channel MOSFET with five vertically stacked 3 nanowire bundle (15 nanowire bundle) according to an embodiment of the present invention. Threshold voltage variation with different L_{G} can be seen in FIG. 18. The threshold voltage varies between approximately −100 mV and approximately +100 mV for different length devices. A likely cause for this variation might relate to size control (for example fin patterning, oxidation uniformity, Ge-concentration) and implantation.

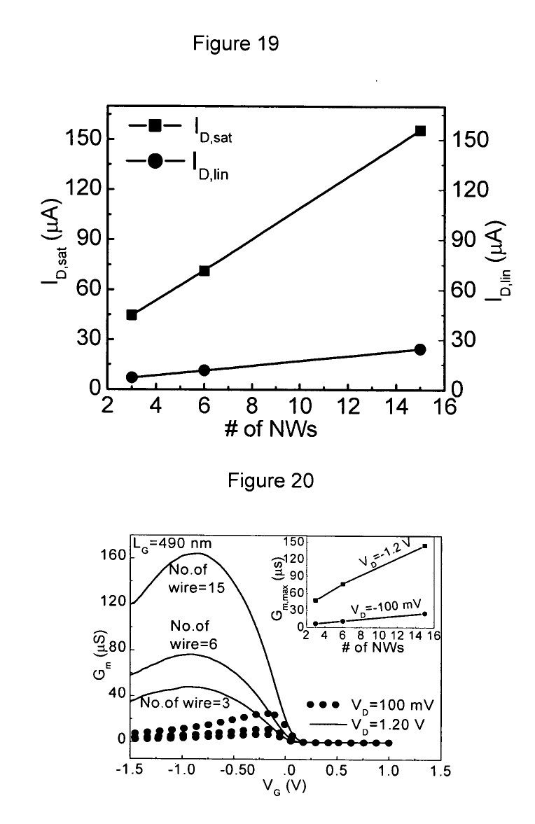

FIG. 19 shows a plot of saturation drain current (I_{DSAT}) with number of nanowires according to an embodiment of the present invention. I_{DSAT}, the saturation current at V_{D}=−V_{dd}(−1.2 V) and V_{gs}=Vₜₕ−V_{dd} and the linear current I_{DLIN}, at V_{D}=−100 mV and Vgs=Vth−V_{dd} were measured as a function of number of nanowires. FIG. 19 shows the linear relationship of I_{DSAT} and I_{DLIN} with the number of nanowires in a 3 nanowire bundle structure. The linear relationship indicates a proportional enhancement in current by each addition of nanowire in the stacked structure.

FIG. 20 shows a plot of transconductance (G_{M}) with gate voltage (V_{G}) of a p-channel MOSFET for a varying number of nanowires according to an embodiment of the present invention. The linear and saturation transconductance Gₘ of p-channel MOSFET transistors with 3, 6 and 15 nanowires as a function of gate voltage is shown in FIG. 20. The maximum Gₘ is the highest for the p-channel MOSFET transistor with 15 nanowires. A linear relation between G_{m,max} and the number of nanowires for both linear and saturation cases can be seen in the inset of FIG. 20. Such excellent scaling of the device performance parameters demonstrates the consistency between parallel arrays of the stacks realized by the present invention.

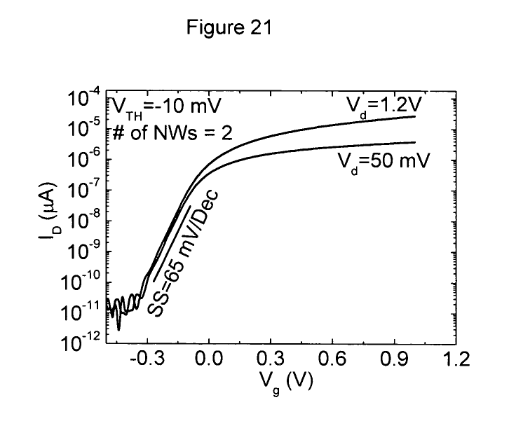

Some results of fabricated n-channel MOSFET transistors are shown in FIG. 21. FIG. 21 shows a I_{D}-V_{G} characteristics plot of a GAA silicon-germanium nanowire n-channel MOSFET with a vertically stacked 2 nanowire bundle according to an embodiment of the present invention. The saturation region and linear region I_{d}-V_{g} characteristics for a single row of vertically stacked 2 nanowire bundle can be seen in FIG. 21. The subthreshold behavior and leakage currents are comparable to the p-channel MOSFET nanowire transistors.

The aforementioned description of the various embodiments has been presented for purposes of illustration and description. It is not intended to be exhaustive or to limit the invention to the precise form disclosed, and obviously many modifications and variations are possible in light of the disclosed teaching. It is intended that the scope of the invention be defined by the claims appended hereto.

1. A method of forming a stacked silicon-germanium nanowire structure on a support substrate comprising:
forming a stacked structure on the support substrate, the stacked structure comprising at least one channel layer and at least one interchannel layer deposited on the channel layer;
forming a fin structure from the stacked structure, the fin structure comprising at least two supporting portions and a fin portion arranged there between;
oxidizing the fin portion of the fin structure thereby forming the silicon-germanium nanowire being surrounded by a layer of oxide; and
removing the layer of oxide to form the silicon-germanium nanowire.

2. The method of claim 1, wherein forming the stacked structure comprises:
forming the channel layer by depositing a silicon layer; and
forming the interchannel layer by depositing a germanium layer.

3. The method of claim 2, wherein forming the interchannel layer is a two-step process, the process comprises:
depositing a layer of silicon-germanium layer on the silicon layer before depositing the germanium layer.

4. The method of claim 1, wherein forming a fin structure from the stacked structure comprises
patterning the fin structure using a lithography process;
patterning the fin portion using an alternating-phase-shift mask; and
etching the fin portion using reactive-ion-etching.

5. The method of claim 1, wherein oxidizing the fin portion of the fin structure is performed by a germanium condensation process.

6. The method of claim 1, wherein removing the layer of oxide surrounding the silicon-germanium nanowire is performed by etching.

7. The method of claim 1, further comprising performing a first heat treatment to repair crystal defects before removal of the layer of oxide surrounding the silicon-germanium nanowire.

8. The method of claim 1, wherein a first insulating layer is arranged between the support substrate and the stacked structure.

9. A method of forming a gate-all-around transistor comprising forming a stacked silicon-germanium nanowire structure that has been formed on a support substrate using the method as defined in claim 1, the method of forming the gate-all-around transistor further comprising:
forming a second insulating layer around the silicon-germanium nanowire;
depositing a conductive layer on the second insulating layer;
forming a gate electrode from the conductive layer;
doping at least the supporting portions with a first dopant.

10. The method of claim 9, further comprising
doping the gate electrode with a second dopant of either similar or opposite conductivity to the first dopant.

11. The method of claim 10, further comprising performing a second heat treatment after doping the gate electrode to ensure uniform diffusion of dopants in the gate electrode.

12. The method of claim 11, further comprising forming a conductive layer on a contact surface of the supporting portions.

13. The method of claim 12, wherein the conductive layer is selected from the group consisting of silicon, polysilicon, amorphous silicon and metal.

14. The method of claim 9, wherein the first dopant is either p-type or n-type.

15. The method of claim 14, wherein the p-type dopant is one or more elements selected from the group consisting of boron, aluminum, gallium and indium.

16. The method of claim 14, wherein the n-type dopant is one or more elements selected from the group consisting of phosphorus and arsenic.

17. A stacked silicon-germanium nanowire structure comprising:
a support substrate;
a stacked fin structure arranged on the support substrate,
wherein
the stacked fin structure comprises at least one channel layer and at least one interchannel layer deposited on the channel layer and
further comprises at least two supporting portions and at least one silicon-germanium nanowire arranged there between.

18. The structure of claim 17, wherein the stacked fin structure comprises a plurality of channel layers and interchannel layers interposed between the channel layers.

19. The structure of claim 17, further comprising a plurality of stacked fin structures arranged horizontally on the support substrate.

20. The structure of claim 17, wherein the silicon-germanium nanowire is located above the support substrate.

21. The structure of claim 17, wherein a first insulating layer is arranged between the support substrate and the stacked fin structure.

22. The structure of claim 17, wherein the channel layer is silicon.

23. The structure of claim 17, wherein the interchannel layer comprises germanium or a combination of silicon-germanium and germanium.

24. A gate-all-around transistor comprising the stacked silicon-germanium nanowire structure as defined claim 17, the gate-all-around transistor further comprising:
a second insulating layer around the silicon-germanium nanowire;
a gate electrode positioned over the second insulating layer; and
at least two doped supporting portions.

25. The transistor of claim 24, further comprising a conductive layer on a contact surface of the supporting portions.

26. The transistor of claim 24, wherein the gate electrode may be doped or undoped.

27. The transistor of claim 26, wherein the doped gate electrode is either p-type or n-type.

28. The transistor of claim 27, wherein the p-type dopant is one or more elements selected from the group consisting of boron, aluminum, gallium and indium.

29. The transistor of claim 27, wherein the n-type dopant is one or more elements selected from the group consisting of phosphorus and arsenic.
